(19) United States
(12) Patent Application Publication
(10) Pub. No.: US 2003/0212939 A1
(43) Pub. Date: Nov. 13, 2003

(54) Method and apparatus for selecting the operational mode of an integrated circuit

(76) Inventor: Ronald N. Baker, Raleigh, NC (US)

Correspondence Address: THOMAS R. FITZGERALD, ESQ., 16 E. MAIN STREET, SUTIE 210, ROCHESTER, NY, 14614-1803, US

(21) Appl. No.: 10/141,752

(22) Filed: May 9, 2002

(51) Int. Cl. G01R 31/28

(52) U.S. Cl. 714/724

(57) ABSTRACT

An integrated circuit includes a power bus configured for being electrically interconnected to at least one supply voltage. An operational mode logic circuit is electrically connected to the power bus and monitors the voltage levels on the power bus. An operational mode signal issued by the operational mode circuit is dependent at least in part upon the occurrence of a predetermined sequence of voltage levels on the power bus. The operational mode signal is activated and places the IC into the second mode of operation when the predetermined sequence of voltage levels occurs on the power bus. The operational mode signal is inactive and places the IC into the first mode of operation when the predetermined sequence of voltage levels does not occur on the power bus.

### FIELD OF THE INVENTION

The present invention relates generally to integrated circuits and, more particularly, to a method and apparatus for placing an integrated circuit into a particular mode of operation.

### BACKGROUND OF THE INVENTION

Integrated circuits (ICs) are often very complex devices from both a structural and functional standpoint. The testing of such structurally and functionally complex devices is often equally complex. Manufacturers typically test ICs by using sophisticated testing machines. The ICs are first placed into a specific operational mode, such as, for example, a test mode, to facilitate testing of the device. In final application or customer use, the IC is generally not intended to operate in these specific operational modes. Further, the specific modes of operation are not usually intended to be accessible to or used by the end customer.

Typically, an IC is placed into a desired operational mode through the application to the IC input pins of a predetermined sequence of one or more input signals. Thus, the IC must be powered up and ready to accept input signals. In order to be ready to accept input signals the IC must complete its power or start-up process, which typically includes turning on voltage pumps, initializing chip logic, etc.

The power or start-up process consumes a certain amount of time, which can be costly and expensive time if this process is being run on a sophisticated test machine or assembly line. Further, certain ICs, such as, for example, synchronous dynamic random access memory (SDRAM) chips and other ICs that use an externally-generated reference voltage, are tested in operational modes that require the temporary disabling of the ICs ability to receive input signals. The method of applying a predetermined sequence of one or more signals in order to place the IC into the desired mode of operation is not compatible with an IC that requires operation in such input-disabling operational modes.

The specific method, i.e., the signals applied and sequence thereof, used to place an IC into a particular mode of operation varies between manufacturers and even between different ICs. Thus, in order to place a particular IC into a desired mode of operation, a manufacturer must apply to the IC input pins the specific signals in the proper sequence to place that particular IC in the desired operational mode. The signals are applied by a piece of equipment, such as, for example, a test machine or test station, which must be configured and/or programmed to apply the signals required to place the particular IC into the desired test mode. If, for example, the manufacturer desires to test a different IC on the same piece of test equipment, that piece of test equipment must be reconfigured and/or reprogrammed to apply the specific signals in the proper sequence required to place that particular IC in the desired mode of operation. The required set up of the signal-applying device and the actual application of the signals consume valuable time, such as, for example, testing or assembly line time.

As stated above, an IC is typically placed into a desired operational mode through the application to the IC input pins of a predetermined sequence of one or more input signals. The testing machine typically supplies the input signals that place the IC or device under test (DUT) into a test mode of operation. Since the IC must first complete the power-on sequence and be prepared to receive input signals, each of the mode-determinative input pins must be supplied with the proper sequence of signals in order to enter the desired test mode of operation. If all mode-determinative input pins are not connected to the tester or receive the appropriate sequence of signals, the IC will be precluded from entering the desired test mode. Thus, since the tester must supply each of the mode-determinative input pins with the appropriate signals, a substantial amount of the tester resources are consumed to place each DUT into the desired test mode of operation.

As an example, a conventional memory chip, such as a DRAM, may require twelve or more address signals be provided to the IC or DUT in order to enter a particular operational mode. One skilled in the art will quickly realize that the number of devices that can be tested in parallel is limited by the requirement of supplying a predefined sequence of input signals to twelve input pins in order to enter a desired mode of operation.

Therefore, what is needed in the art is a method and apparatus that places an IC into a desired mode of operation during or contemporaneously with the power up sequence of the IC.

Furthermore, what is needed in the art is a method and apparatus that places an IC into a desired mode of operation without requiring the IC to be prepared to accept input signals.

Still further, what is needed in the art is a method and apparatus that places an IC into a desired mode of operation in a reduced amount of time.

Even further, what is needed in the art is a method and apparatus that reduces the testing machine resources necessary in order to place an IC into a desired mode of operation.

Yet further, what is needed in the art is a method and apparatus that reduces the number of signals required in order to place an IC into a desired mode of operation.

Moreover, what is needed in the art is a method and apparatus that enables entry into a desired operational mode with fewer applied signals thereby reducing the amount of testing machine resources devoted to operational mode entry, and increasing the number of devices that can be tested in parallel on the testing machine.

### SUMMARY OF THE INVENTION

The present invention provides an integrated circuit that is placed into a desired mode of operation by sequencing of the voltage levels of the supply voltages that power the integrated circuit.

The invention comprises, in one form thereof, an integrated circuit having a power bus configured for being electrically interconnected to at least one supply voltage. An operational mode logic circuit is electrically connected to the power bus and monitors the voltage levels on the power bus. An operational mode signal issued by the operational mode circuit is dependent at least in part upon the occurrence of a predetermined sequence of voltage levels on the power bus. The operational mode signal is activated and places the IC into the second mode of operation when the predetermined sequence of voltage levels occurs on the power bus. The operational mode signal is inactive and places the IC into the first mode of operation when the predetermined sequence of voltage levels does not occur on the power bus.

An advantage of the present invention is that the IC is placed into a desired mode of operation during or contemporaneously with the power up sequence of the IC.

Another advantage of the present invention is that the desired mode of operation is entered without requiring the IC to be prepared to accept input signals.

A further advantage of the present invention is that the desired mode of operation is entered in a reduced amount of time.

A still further advantage of the present invention is that the testing resources required to place the IC into a desired mode of operation are substantially reduced.

An even further advantage of the present inventions is the number of signals required in order to place an IC into a desired mode of operation are substantially reduced.

A yet further advantage of the present invention is entry into a desired operational mode occurs with fewer applied signals thereby reducing the amount of testing machine resources required for operational mode entry, and increasing the number of devices that can be tested in parallel on the testing machine.

### BRIEF DESCRIPTION OF THE DRAWINGS

The above-mentioned and other features and advantages of this invention, and the manner of attaining them, will become appreciated and be more readily understood by reference to the following detailed description of one embodiment of the invention in conjunction with the accompanying drawings, wherein:

FIG. 1 is a block diagram of one embodiment of an integrated circuit of the present invention; and

FIG. 2 is one example of a sequence of exemplary signals used to place the integrated circuit of FIG. 1 into a desired mode of operation.

Corresponding reference characters indicate corresponding parts throughout the several views. The exemplification set out herein illustrates one preferred embodiment of the invention, in one form, and such exemplification is not to be construed as limiting the scope of the invention in any manner.

### DETAILED DESCRIPTION OF THE DRAWINGS

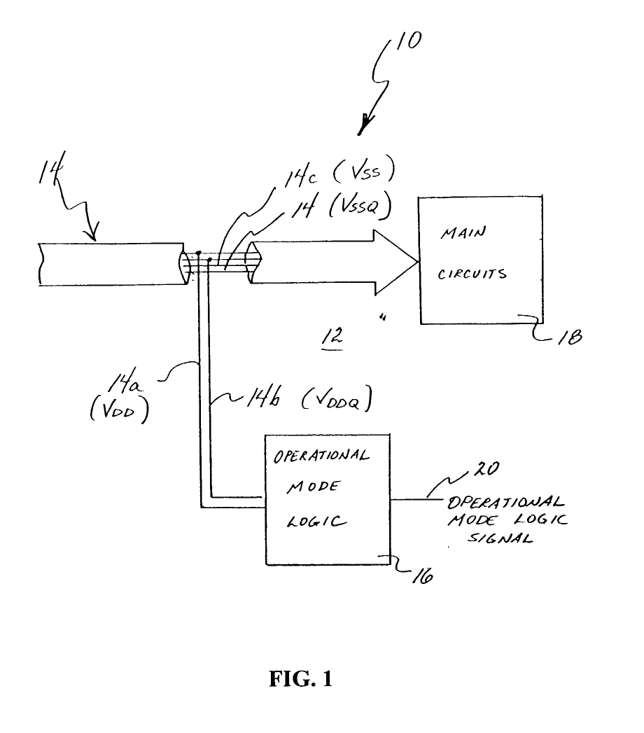

Referring now to FIG. 1, one embodiment of an integrated circuit (IC) of the present invention is shown. IC 10 is formed on substrate 12, and includes power bus 14, operational mode logic circuit 16 and main circuitry 18. IC 10 includes a first mode of operation, such as, for example, a normal use operational mode, and a second mode of operation, such as, for example, a test or desired operational mode.

Power bus 14 interconnects supply voltages, such as, for example, V_{DD}, V_{DDQ}, V_{SS} and V_{SSQ}, to main circuitry 18 thereby connecting IC 10 with the supply voltages necessary for the operation thereof Power bus 14 includes a plurality of individual power bus or supply voltage lines 14a, 14b, 14c . . . 14z, each of which carry a respective supply voltage.

Operational mode logic circuit 16, such as, for example, one or more logic gates or a sequencing logic circuit, is electrically connected to and receives the supply voltages via power bus 14. More particularly, operational mode logic circuit 16 is electrically connected to supply voltage lines 14a and 14b, and thereby receives supply voltages V_{DD} and V_{DDQ}. Operational mode logic circuit 16 monitors the supply voltages carried by supply voltage lines 14a, 14b, and detects a predetermined sequence of the voltage levels carried thereby. Operational mode logic circuit 16 issues operational mode signal 20 upon detecting the occurrence of the predetermined sequence of voltage levels on supply voltage lines 14a, 14b. Operational mode signal 20, as is know in the art, places IC 10 into the desired or test mode of operation.

Main circuitry 18 is any circuitry that can be placed on an integrated circuit, such as, for example, a memory array, that performs the function for which IC 10 is intended.

In use, IC 10 is placed into the desired mode of operation, such as, for example, a test mode of operation, upon the occurrence of a predetermined sequence of the voltage levels carried by power bus 14. More particularly, operational mode logic circuit 16 is electrically connected to supply voltage lines 14a, 14b. Supply voltage lines 14a, 14b are sequenced, i.e., the voltage levels thereof are stepped or toggled between high and low logic levels at predetermined times and/or for predetermined periods of time. The supply voltage lines 14a, 14b are sequenced by, for example, a piece of test equipment or a dedicated sequencing circuit.

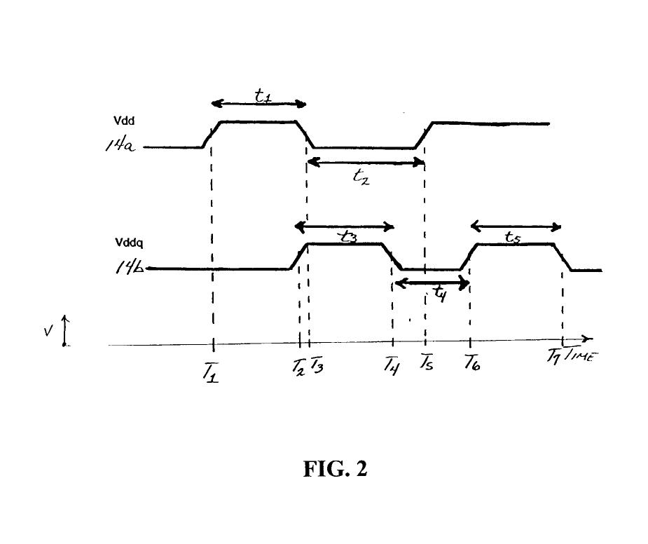

Referring now to FIG. 2, one example of a predetermined sequence of supply voltage lines 14a, 14b, carrying supply voltages V_{DD}, V_{DDQ}, respectively, used to place IC 10 into a desired mode of operation is shown. Supply voltage line 14a, or V_{DD}, is sequenced first from a low logic voltage level to a high logic voltage level at time T₁ for a period of time t₁ then to a low voltage level at time T₃ for a period of time t₂, and then to a high voltage level at time T₅ for an indefinite period of time. Supply voltage line 14b, or V_{DDQ}, is sequenced first from a low voltage level to a high voltage level at time T₂ for a period of time t₃, then to a low voltage level at time T₄ for a period of time t₄, then to a high voltage level at time T₆ for a period of time t₅, and then to returned to a low logic level at time T₇ for an indefinite period of time. The predetermined sequence of supply voltage lines 14a, 14b is detected and decoded by operational mode logic circuit 16, such as, for example, a conventional sequential logic circuit. Upon detecting the predetermined sequence of supply voltage lines 14a, 14b, operational mode logic circuit 16 activates operational mode signal 20 which, in turn, places IC 10 in the desired or test mode of operation.

The sequencing of the supply voltage lines 14a, 14b is preferably performed during the power-up or initialization sequence of IC 10. Conventionally, ICs are placed into a desired operational mode, such as a test mode of operation, through the application of a predetermined sequence of input signals. In order for the input signals to be accepted, the IC would have to complete its power-up or initialization process. Thus, in order to be placed into the desired or test mode of operation the IC must complete its start-up process. In contrast, by sequencing the supply voltage levels, i.e., the voltage levels carried by supply voltage lines 14a, 14b, IC 10 need not have completed its power-up sequence nor be prepared to accept input signals in order to be placed into a desired mode of operation. Thus, IC 10 is placed into a desired or test mode of operation more expediently than is possible under the conventional process described above.

IC 10 is configured to enter the first or a default mode of operation if the voltage levels carried by power bus 14 are not sequenced in the predetermined manner. If the voltage levels carried by power bus 14 do not sequence in accordance with the predetermined manner, operational mode signal 20 remains inactive and IC 10 enters the first or default mode of operation.

In the embodiment shown, supply voltage lines 14a, 14b and/or supply voltages V_{DD}, V_{DDQ} are sequenced in a predetermined manner which is decoded by operational logic circuit 16 to thereby place IC 10 in a desired mode of operation. However, it is to be understood that the operational logic circuit 16 of the present invention can be alternately configured to detect a virtually infinite number of predetermined sequences of one or more of the supply voltage lines of IC 10. Further, it is to be understood that one or more of the supply voltage lines can be sequenced to correspond with and be detected by a particular embodiment of operational mode logic circuit 16.

In the embodiment shown, IC 10 includes power bus 14 having a plurality of individual power bus or supply voltage lines 14a, 14b, 14c, . . . , 14z, each of which carry a respective supply voltage. However, it is to be understood that the apparatus and method of the present invention can be alternately configured, such as, for example, with a greater or lesser number of individual supply voltage lines to correspond with the supply voltage requirements of a particular integrated circuit.

In the embodiment shown, test mode logic circuit 16 is electrically connected to supply voltage lines 14a and 14b, and thereby monitors the voltage level of those supply voltage lines for a predetermined sequence. However, it is to be understood that the present invention can be alternately configured, such as, for example, with a greater or lesser number of supply voltage lines being connected to and monitored by the test mode logic circuit.

In the embodiment shown, a predetermined sequence of the voltage levels of supply voltage lines 14a and 14b is detected by operational mode logic circuit 16. The predetermined sequence corresponds to the second or desired mode (i.e., non-default mode) of operation for IC 10. IC 10 enters the default mode of operation when the predetermined sequence of voltage levels does not occur on the supply voltage lines, and IC 10 enters the desired or second mode of operation when the predetermined sequence is detected on the supply voltage lines. However, it is to be understood that the present invention can be alternately configured, such as, for example, to select between a plurality of operational modes indicated by a plurality of corresponding predetermined sequences of the voltage levels of the supply voltage lines.

While this invention has been described as having a preferred design, the present invention can be further modified within the spirit and scope of this disclosure. This application is therefore intended to cover any variations, uses, or adaptations of the present invention using the general principles disclosed herein. Further, this application is intended to cover such departures from the present disclosure as come within the known or customary practice in the art to which this invention pertains and which fall within the limits of the appended claims.

What is claimed:

1. An integrated circuit having a first and second mode of operation, said integrated circuit being powered by at least one supply voltage, said integrated circuit comprising:
a power bus configured for being electrically interconnected to the at least one supply voltage; and
an operational mode logic circuit electrically connected to said power bus, said operational mode logic circuit monitoring a voltage level of the power bus, an operational mode signal being issued by said operational mode logic circuit dependent at least in part upon the occurrence of a predetermined sequence of the voltage level on said power bus, said operational mode signal being active and placing said integrated circuit into the second mode of operation when said predetermined sequence of voltage levels occurs on said power bus, said operational mode signal being inactive and placing said integrated circuit into the first mode of operation when said predetermined sequence of voltage levels does not occur on said power bus.

2. The integrated circuit of claim 1, wherein said power bus includes a plurality of supply voltage lines, each of said plurality of supply voltage lines configured for being connected to and carrying a corresponding supply voltage, at least one of said plurality of supply voltage lines being electrically connected to said operational mode logic circuit, said operational mode signal being activated dependent at least in part upon the occurrence of a predetermined sequence of voltage levels on said at least one supply voltage line.

3. The integrated circuit of claim 1, said integrated circuit having a power-up sequence, wherein said operational mode signal must become active at least one of prior to or within a predetermined amount of time following the completion of said power-up sequence in order for said integrated circuit to be placed into said second mode of operation.

4. An operational mode logic circuit for use with an integrated circuit, the integrated circuit being formed on a substrate and having a first and second mode of operation, said integrated circuit including a power bus electrically interconnected to at least one supply voltage, said operational mode logic circuit configured for being electrically connected to said power bus and for monitoring at least one voltage level on the power bus, an operational mode signal activated by said operational mode logic circuit dependent at least in part upon the occurrence of a predetermined sequence of the at least one voltage level on the power bus.

5. The operational mode logic circuit of claim 4, the power bus including a plurality of supply voltage lines each connected to a corresponding supply voltage, said operational mode logic circuit configured for being electrically connected to at least one of the plurality of supply voltage lines, said operational mode signal being activated dependent at least in part upon the occurrence of a predetermined sequence of voltage levels on said at least one supply voltage line.

6. The test mode logic circuit of claim 4, wherein said operational mode logic circuit is integral with the substrate.

7. A method of placing an integrated circuit into an operational mode, said integrated circuit being electrically connected to at least one supply voltage, said method comprising the steps of:
varying a voltage level of the at least one supply voltage to produce a predetermined sequence of voltage levels;
monitoring the voltage level of the at least one supply voltage to detect the predetermined sequence; and
placing the integrated circuit into a mode of operation dependent at least in part upon said monitoring step.

8. The method of claim 7, wherein said varying step includes varying for predetermined periods of time the voltage levels of the at least one supply voltage.

9. The method of claim 7, wherein said varying step is performed by one of a testing machine and a sequencing circuit.

10. The method of claim 7, wherein said monitoring step comprises an operational mode logic circuit electrically interconnected with at least one of the supply voltages, said operational mode logic circuit activating at least one operational mode signal upon detecting the predetermined sequence to thereby place the integrated circuit into a mode of operation corresponding to the predetermined sequence.

11. The method of claim 7, comprising the further step entering a default mode of operation when the predetermined sequence is not detected.

12. The method of claim 7, wherein the integrated circuit performs a power up procedure, said method being at least partially executed during the power up procedure.

13. The method of claim 12, wherein said method is completed prior to the completion of the power up procedure.

14. The method of claim 7, the integrated circuit having a plurality of operational modes, the predetermined sequence comprising a plurality of predetermined sequences, each of said plurality of predetermined sequences corresponding to one of said plurality of operational modes.
